(19) United States
(12) Patent Application Publication
(10) Pub. No.: US 2013/0100562 A1
(43) Pub. Date: Apr. 25, 2013

(54) ELECTROSTATIC DISCHARGE CLAMP WITH CONTROLLED HYSTERESIS INCLUDING SELECTABLE TURN ON AND TURN OFF THRESHOLD VOLTAGES

(71) Applicant: Intersil Americas LLC, Milpitas, CA (US)

(72) Inventor: Gregg D. Croft, Palm Bay, FL (US)

(73) Assignee: INTERSIL AMERICAS LLC, Milpitas, CA (US)

(21) Appl. No.: 13/714,096

(22) Filed: Dec. 13, 2012

Related U.S. Application Data
(63) Continuation of application No. 12/721,172, filed on Mar. 10, 2010.
(60) Provisional application No. 61/255,548, filed on Oct. 28, 2009.

(51) Int. Cl. H02H 9/04; H05K 3/32

(52) U.S. Cl. CPC H02H 9/044; H05K 3/32
USPC 361/56; 29/825

(57) ABSTRACT

An electrostatic discharge (ESD) clamp for coupling between first and second nodes for providing ESD protection including first and second voltage threshold circuits. The clamp circuit limits operating voltage between the first and second nodes to a maximum level when activated. The first and second voltage threshold circuits each have a selectable threshold voltage, such as by coupling one or more voltage threshold devices in series. The first and second voltage threshold circuits trigger to turn on the clamp circuit when the operating voltage increases above a first voltage threshold. The voltage threshold circuits are turned off to turn off the clamp circuit when the operating voltage decreases to the second threshold voltage. The second threshold voltage may be selected at any level above the nominal operating voltage to prevent the clamp from latching.

### CROSS-REFERENCE TO RELATED APPLICATIONS

This application is a continuation of pending U.S. application Ser. No. 12/721,172, filed on Mar. 28, 2010, pending, which claims the benefit of U.S. Provisional Application Ser. No. 61/255,548, filed on Oct. 28, 2009, which are both hereby incorporated by reference in their entireties for all intents and purposes.

### BRIEF DESCRIPTION OF THE DRAWINGS

The benefits, features, and advantages of the present invention will become better understood with regard to the following description, and accompanying drawings where:

FIG. 1 is a schematic and block diagram of an integrated circuit (IC) incorporating an ESD clamp circuit with controlled hysteresis implemented according to one embodiment;

FIG. 2 is a schematic and block diagram of an IC incorporating the ESD clamp circuit of FIG. 1 using a dual diode ESD protection scheme similar to FIG. 1 except with floating ESD rails;

FIGS. 3-6 are schematic diagrams of ESD clamp circuits with controlled hysteresis according to corresponding embodiment which may be used as the ESD clamp circuit of FIG. 1;

FIG. 7 is a schematic diagram of an ESD clamp circuit with controlled hysteresis according to another embodiment similar to that shown in FIG. 5 and including a disable circuit for disabling the clamp circuit when source voltage is provided;

FIGS. 8-14 illustrate various embodiments of voltage threshold devices which may be used in any of the ESD clamp circuits of FIGS. 1-7; and

FIG. 15 is a simplified schematic diagram of an integrated circuit pre-configured to implement a customizable VT circuit ZX according to one embodiment.

### DETAILED DESCRIPTION

The following description is presented to enable one of ordinary skill in the art to make and use the present invention as provided within the context of a particular application and its requirements. Various modifications to the preferred embodiment will, however, be apparent to one skilled in the art, and the general principles defined herein may be applied to other embodiments. Therefore, the present invention is not intended to be limited to the particular embodiments shown and described herein, but is to be accorded the widest scope consistent with the principles and novel features herein disclosed.

An electrostatic discharge (ESD) clamp circuit according to embodiments described herein applies to the field of protecting integrated circuits from damage due to electrostatic discharge. ESD clamp circuits are commonly used to limit the voltage that can appear across areas of an integrated circuit (IC) that are sensitive to damage from ESD. An ESD clamp circuit as described herein is coupled in parallel to the underlying circuitry on the IC that it protects. During an ESD event, the ESD clamp circuit turns on and limits the voltage across, and diverts the destructive current around, the ESD sensitive circuitry. For a voltage-triggered ESD clamp circuit it is desired to have the clamp only turn on (initially trigger) when a relatively high voltage threshold is reached to avoid unwanted triggering during normal operation. However, once triggered, it is desired that the clamp circuit stay on until a lower voltage threshold is reached to provide increased protection from ESD damage. Therefore, the magnitude of the voltage at which the ESD clamp circuit transitions from the off to the on state is greater than the magnitude of the voltage at which the clamp circuit transitions from the on state to the off state. An ESD clamp circuit according to the various embodiments includes a controlled hysteresis. The term “hysteresis” as used herein means that the ESD clamp circuit responds differently depending on whether it is transitioning from the off state to the on state or from the on state to the off state. The term “controlled hysteresis” as used herein means that both of the turn-on and turn-off set points are separately customizable or selectable.

ESD clamp circuits are known which have a configurable turn-on voltage set point sufficiently above a nominal operating voltage level. Silicon-controlled rectifier (SCR) type ESD clamp circuits, for example, turn on at a sufficiently high voltage level but often remain activated as long as current is available. Thus, many SCR-type ESD clamp circuits remain latched and do not turn off until after the voltage level reaches a relatively low voltage such as below the nominal voltage level. Devices incorporating such SCR-type clamp circuits had to be powered down to reset the clamp circuit and allow normal operation. It is often desired to ensure that the ESD clamp circuit turns off before the voltage drops back down to the nominal operating voltage level to avoid a latched condition and to prevent ESD exposure while enabling normal operation. ESD clamp circuits with hysteresis are known which have a turn-off or “holding” or “snap-back” voltage at some point below the turn-on set point. Yet the specific holding voltage has been difficult to configure and often must be designed on a case-by-case basis. For example, the particular turn-off point may not be guaranteed and may vary from part to part or with different operating conditions. Also, the particular turn-off point may be designed for a specific operating voltage range and may require additional engineering design for different voltage levels or for different parts designed for different customers. Thus, conventional ESD clamp circuits did not have controlled hysteresis.

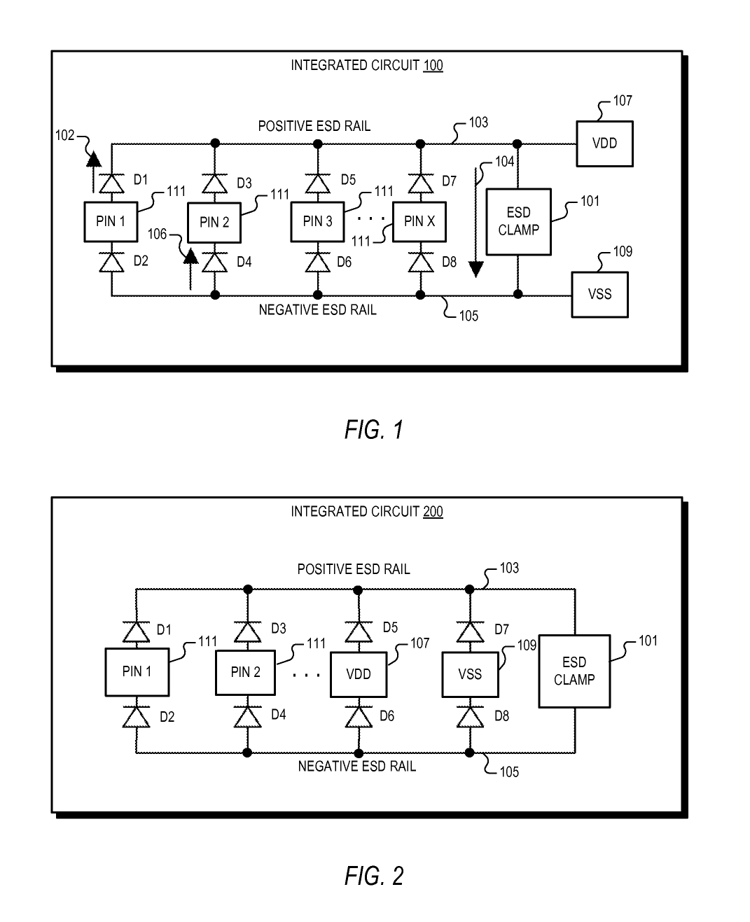

FIG. 1 is a schematic and block diagram of an integrated circuit (IC) 100 incorporating an ESD clamp circuit 101 with controlled hysteresis implemented according to one embodiment. The IC 100 uses an ESD protection scheme referred to as dual diode protection or up/down diode protection. The ESD clamp circuit 101 is coupled between a positive ESD rail 103 and a negative ESD rail 105. In this case, the positive ESD rail 103 is coupled to a VDD source voltage pin 107 and the negative ESD rail 105 is coupled to a VSS reference voltage pin 109. The rails 103 and 105 may be coupled directly to source voltage pads or voltage planes within the IC 100 rather than directly to the pins 107 and 109 as understood by those skilled in the art. The IC 100 further includes any number of input/output (I/O) pins 111, independently shown as PIN 1, PIN 2, PIN3, . . . , PIN X. A pair of diodes are connected between each pin and the source voltage pins 107 and 109. As shown, a first set of diodes D1, D3, D5, . . . , D7 have their cathodes coupled to the positive ESD rail 103 and a second set of diodes D2, D4, D6, . . . , D8 have their anodes coupled to the negative ESD rail 105. Each of the diodes D1, D3, D5, . . . , D7 has its anode coupled to a respective one of the pins PIN 1, PIN 2, PIN3, . . . , PIN X, and each of the diodes D2, D4, D6, . . . , D8 has its cathode coupled to a respective one of the pins PIN1, PIN 2, PIN3, . . . , PIN X.

The dual diode protection scheme refers to the pair of diodes connected to each pin of the IC 101. These diodes are used to steer the large currents generated by an ESD event to the ESD clamp circuit 101 that is shared by all the pins. During an ESD event, the ESD clamp circuit 101 turns on and shunts the current while minimizing the on chip voltage drop. Once the ESD pulse goes away, the ESD clamp circuit 101 turn offs to avoid interfering in the normal operation of the IC 100. As an example, for a positive ESD pulse applied from PIN 1 to PIN 2 causes a current pulse to travel up through diode D1 as indicated by arrow 102, down through the ESD clamp circuit 101 as indicated by arrow 104, and then up through diode D4 as indicated by arrow 106. Similar paths exist between all I/O pin pairs of the IC 100. This arrangement is designed such that the diodes only conduct ESD current in a forward direction. This allows their area to be made much smaller than otherwise needed to handle the same amount of current in the reverse direction. This reduction in diode area also minimizes their capacitance and leakage current. During normal operation the leakage current from the upper diode flows toward the pin while the leakage current from the lower diode flows away from of the pin. These opposing leakage currents tend to partially cancel each other out, further reducing the net leakage current due to the ESD network seen at the pins of the IC 100.

FIG. 2 is a schematic and block diagram of an IC 200 incorporating the ESD clamp circuit 101 using a dual diode ESD protection scheme similar to FIG. 1 except with floating ESD rails. In this case, the I/O pins 111 and the ESD clamp circuit 101 are included and coupled between the positive and negative ESD rails 103 and 105 in substantially the same manner as in FIG. 1. In this case, however, the VDD pin 107 is coupled to the anode of diode D5 and to the cathode of diode D6, and the VSS pin 109 is coupled to the anode of diode D7 and to the cathode of diode D8. The cathode of D7 is coupled to the positive ESD rail 103 and the anode of diode D8 is coupled to the negative ESD rail 105. The scheme of FIG. 2 may be used for an application in which an I/O pin operates at voltages outside the normal supply range. For example, if an input signal is required to go several volts above the positive supply voltage VDD during normal operation, the positive ESD rail 103 is floated above VDD. Under normal operation the positive ESD rail 103 charges to a voltage very near VDD. When the input is pulled higher than VDD, however, the voltage on the positive ESD rail 103 is able rise with it. This event causes very little DC current to flow because the positive ESD rail 103 is not directly tied to VDD but instead is tied to VDD through the reversed-biased diode D5. This same technique can be used with the negative ESD rail 105 for signals that go below the negative supply VSS.

An electrostatic discharge clamp with controlled hysteresis including selectable turn on and turn off threshold voltages as described herein is particularly advantageous for protecting integrated circuits and chips, but is not limited to integrated embodiments and may be implemented using discrete logic or devices and components. ESD protection devices and structures in integrated embodiments are layout sensitive. Measures are usually taken to minimize the series resistance of the ESD discharge path, such as using very large transistors, diodes, and metal bus lines to conduct the current. Care is taken to prevent current from concentrating or crowding in any one area of a device; instead, measures are taken to spread the discharge current out as evenly as possible. Many of these layout techniques are known by those of ordinary skill in the art.

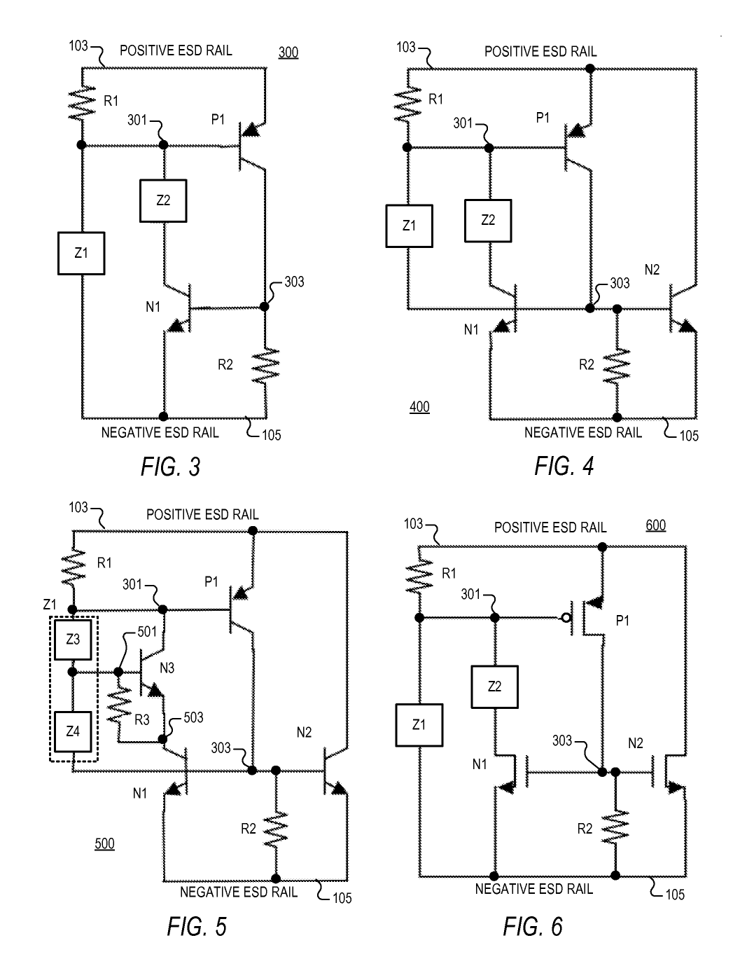

FIG. 3 is a schematic diagram of an ESD clamp circuit 300 with controlled hysteresis according to one embodiment which may be used as the ESD clamp circuit 101. A PNP bipolar junction transistor (BJT) P1 has its emitter coupled to the positive ESD rail 103, its base coupled to node 301 and its collector coupled to node 303. A resistor R1 is coupled between rail 103 and node 301. An NPN BJT N1 has its base coupled to node 303 and its emitter coupled to the negative ESD rail 105. A resistor R2 is coupled between node 303 and rail 105. A first voltage threshold (VT) circuit Z1 is coupled between node 301 and rail 105 and a second VT circuit Z2 is coupled between node 301 and the collector of N1. During normal operation, the positive ESD rail 103 is normally held at about the voltage of VDD, or it may float somewhat higher in a floating configuration such as shown in FIG. 2. During normal operation, the negative ESD rail 105 is normally held at about the voltage of VSS, or it may float somewhat lower in a floating configuration. As described further described below, the threshold voltage of each VT circuit Z1 and Z2 is selectable or customized to program turn-on and turn-off set points of the ESD clamp circuit 300.

During normal operation, a nominal voltage level is applied between the rails 103 and 105, in which the nominal voltage level is lower than the voltage thresholds of Z1 and Z2. In this manner, Z1 and Z2 are off allowing little or no current flow. Thus, the resistors R1 and R2 have little or no current flow so that node 301 is pulled to the voltage of rail 103 and node 303 is pulled down to the voltage of rail 105. In this manner, P1 is normally held off by resistor R1 and N1 is normally held off by resistor R2. During an ESD event upon application of a high voltage ESD pulse, the voltage between the positive and the negative ESD rails 103 and 105 increases. When the voltage of the ESD pulse reaches the voltage threshold of Z1, current starts to flow through R1 and Z1. As the voltage of the ESD pulse rises, current increases until eventually the voltage drop across R1 forward biases the base-to-emitter junction of P1 causing it to turn on. The clamp trigger voltage is the base-to-emitter voltage (VBE) of P1 plus the voltage threshold of Z1. The collector current of P1 causes a voltage drop in R2 that forward biases the base-emitter junction of N1 causing it to also turn on. If the breakdown voltage of Z2 is less than Z1, then current also flows through Z2 and N1. This current acts as additional base current for P1 causing additional collector current to flow through P1, which further acts as additional base current for N1. In this manner, a positive feedback loop occurs between transistors P1 and N1 driving both of them into hard conduction. Thus, several current paths are opened to discharge the voltage of the ESD pulse. A primary current path is the collector to emitter of P1+base to emitter of N1. Additional current paths are provided through Z1 and Z2 (in which the amount of current depends on the particular configuration of Z1 and Z2), including the emitter to base of P1+Z1, and P1+Z2+the collector to emitter of N1. Additional limited current paths exist through the resistors R1 and R2.

As the ESD pulse is discharged, the voltage across the positive to negative ESD rails 103 and 105 decreases. At some point this voltage decreases enough so that Z1 exits breakdown. The positive feedback loop formed by P1, N1 and Z2, however, continues to keep both P1 and N1 on. As the voltage across Z2 drops further to its threshold voltage, Z2 turns off which terminates base current flow for P1. Z2 turning off breaks the positive feedback loop and both P1 and N1 turn off, so that the ESD clamp circuit 300 turns off after substantially dissipating the ESD pulse.

The hysteresis for the ESD clamp circuit 300 is controlled by Z1 and Z2. The threshold voltage of Z1 plus the VBE of P1 sets the voltage at which the ESD clamp circuit 300 transitions from the off state to the on state effectively defining the maximum allowable voltage level of the ESD pulse. Although the exact value of the VBE of P1 may not be known, the VBE of P1 generally falls within a known range. Further, any uncertainty of VBE is relatively small compared to the typical threshold voltage of Z1. For example, the VBE of a BJT generally falls within the range of about 0.5V to about 1V. The threshold voltage of Z1 is selected and thus specifically configured to customize the turn on voltage of the ESD clamp circuit 300. The threshold voltage of Z2, plus the VBE of P1 and the saturation voltage (VSAT) of N1 sets the voltage at which the ESD clamp circuit 300 transitions from the on state to the off state. Again, the saturation voltage VSAT of N1 also generally falls within a known range, such as about 0.1V to about 0.5V for a BJT. Since the voltage ranges VBE of P1 and the VSAT of N1 are both known and relatively small, the threshold voltage of Z2 is selected and thus specifically configured to customize the turn off voltage of the ESD clamp circuit 300. In one embodiment, the turn on and turn off voltages are both selected to be greater than the normal operating voltage range of the rails 103 and 105 to safely dissipated an ESD pulse and ensure protection against damage, and further to ensure that the ESD clamp circuit 300 turns off above the normal operating voltage range of the IC. In this manner, when the IC is operating in a circuit, the ESD clamp circuit 300 does not latch and thus allows normal operation to continue after the ESD pulse is dissipated.

FIG. 4 is a schematic diagram of an ESD clamp circuit 400 with controlled hysteresis according to another embodiment which may be used as the ESD clamp circuit 101. The ESD clamp circuit 400 has similar features as the ESD clamp circuit 300 in which similar components assume identical reference numerals. In this case, NPN BJT N2 is added to provide an additional discharge path for the ESD current. The collector of N2 is coupled to the positive ESD rail 103, its emitter is coupled to the negative ESD rail 105, and its base is coupled to node 303. In this configuration, P1 provides base current for N2 as well as N1. The current path of N2 is connected directly across the positive and negative ESD rails 103 and 105 to provide a low impedance ESD discharge path. Another difference of the ESD clamp circuit 400 is that Z1 is not coupled to the negative ESD rail 105 but instead is coupled between nodes 301 and 303. This allows the trigger current that flows through Z1 during an ESD event to create a voltage drop across both R1 and R2, triggering both P1 and N1 instead of just P1.

Operation of the ESD clamp circuit 400 is similar to that of the ESD clamp circuit 300. During normal operation, a nominal voltage level is applied between the rails 103 and 105, so that the voltage thresholds of Z1 and Z2 are not met and they are both off with little or no current flow. The resistor R1 pulls node 301 high keeping P1 off and the resistor R2 pulls node 303 low keeping both N1 and N2 off. In this case, the threshold voltage of Z1 plus the VBE of P1 and the VBE of both N1 and N2 in parallel sets the voltage at which the ESD clamp circuit 400 transitions from the off state to the on state effectively defining the maximum allowable voltage level of the ESD pulse. In response to an ESD pulse having a voltage which rises to the maximum level, Z1 begins drawing current through both resistors R1 and R2. Eventually the voltage drop across R1 forward biases the base-emitter junction of P1 causing it to turn on, and the voltage drop across R2 (from current through Z1 and P1) forward biases the base-emitter junctions of N1 and N2 turning them both on. If the voltage threshold of Z2 is lower than that of Z1, Z2 turns on and N1 draws current through Z1 providing additional base current for P1. A positive feedback loop occurs between transistors P1 and N1 driving them both along with N2 into hard conduction. The ESD pulse is discharged through several separate current paths, including the collector to emitter path of N2, the collector to emitter of P1+the base to emitter paths of N1 and N2, P1+Z1+(N1 and N2), and P1+Z2+N1. Additional limited current paths exist through the resistors R1 and R2.

As the ESD pulse is discharged, the voltage across the positive to negative ESD rails 103 and 105 decreases. At some point this voltage decreases enough so that Z1 exits breakdown and stops current flow. Assuming the voltage threshold of Z2 is lower than that of Z1, the positive feedback loop formed by P1, N1 and Z2, continues to keep both P1 and N1 on. The threshold voltage of Z2, plus the VBE of P1 and the saturation voltage VSAT of N1 sets the voltage at which the ESD clamp circuit 300 transitions from the on state to the off state. When the voltage across the rails 103 and 105 decreases to this level, the voltage across Z2 drops to its threshold voltage and Z2 turns off stopping current flow of base current for P1. Z2 turning off breaks the loop and P1, N1 and N2 turn off, so that the ESD clamp circuit 400 turns off after dissipating the ESD pulse.

Since the VBEs of P1, N1 and N2 are within relatively small known voltage ranges, the threshold voltage of Z1 is selected or otherwise configured to customize the turn on voltage of the ESD clamp circuit 400. Since the VSAT of N1 is also relatively small and within a known voltage range, the threshold voltage of Z2 is selected or otherwise configured to customize the turn off voltage of the ESD clamp circuit 400. In one embodiment, the turn on and turn off voltages are both selected to be greater than the normal operating voltage range of the rails 103 and 105 to ensure protection against damage that would otherwise be caused by an ESD pulse, and to ensure that the ESD clamp circuit 400 turns off and does not latch so as to allow normal operation to continue after the ESD pulse is dissipated.

FIG. 5 is a schematic diagram of an ESD clamp circuit 500 with controlled hysteresis according to another embodiment which may be used as the ESD clamp circuit 101. The ESD clamp circuit 500 has similar features as the ESD clamp circuit 400 in which similar components assume identical reference numerals. For the ESD clamp circuit 500, the VT circuit Z1 is split into two VT circuits Z3 and Z4 with an intermediate junction coupled to node 501. The VT circuit Z2 of the ESD clamp circuit 400 is replaced by NPN transistor N3 having its base coupled to node 501, its collector coupled to node 301 and its emitter coupled to a node 503 which is further coupled to the collector of N1. A resistor R3 is coupled between the base and emitter of N3. Depending upon the configuration of Z2, the NPN transistor N3 may be better suited than Z2 to handle the relatively large currents that flow into the collector of N1 during an ESD event. For example, if Z2 is otherwise implemented with a stack of one or more reverse or Zener diodes, then the resistive nature of the Zener diodes tends to restrict current flow to N1 during the ESD event. N3 has significantly less resistance than Zener diodes, so that it allows greater current flow to N1 when turned on.

The ESD clamp circuit 500 operates in a similar manner as the ESD clamp circuit 400 during an ESD event. The turn on voltage for the ESD clamp circuit 500 is set by the sum of the threshold voltage of Z1 (which is the combined threshold voltages of Z3 plus Z4) plus the VBE of P1 plus the VBE of N1 (or the VBEs of N1 & N2 in parallel, which is essentially the same as the VBE of either one). Once the ESD clamp circuit 500 is activated, the ESD pulse is discharged through several separate current paths, including N2, P1+(N1 and N2), P1+N3+N1, P1+Z3+Z4+(N1 and N2), P1+Z3+N3+N1, along with several limited current paths associated with the resistors R1, R2, and R3. The turn off voltage is set by the threshold voltage of Z3, plus the VBEs of P1 and N3, plus the VSAT of N1. R3 is included to ensure N3 turns off. Since the VBEs of P1 and N1-N3 and the VSAT of N1 are relatively small and within known voltage ranges, the turn on and turn off voltages are easily programmed by customizing the threshold voltages of Z3 and Z4. The combined threshold voltage of Z3+Z4 (or Z1) determines the turn on voltage and the threshold voltage of Z3 alone determines the turn off voltage. In one embodiment the VT circuit Z1 is implemented as a stack of voltage threshold devices, as further described below, in which node 503 is coupled to a selected intermediate junction of the stack.

During an ESD event, the positive ESD rail 103 increases in voltage relative to the negative ESD rail 105 as previously described. The ESD pulse voltage appears across the series combination of Z3 and Z4 and when the combined threshold voltage of Z3 and Z4 is reached, current flows down through R1 into Z3 and Z4 and out through R2. This forward biases the base emitter junctions of P1, N1, and N2. As N1 comes on the base-emitter junction of N3 is forward biased causing it to conduct. The collector current of N1 and N3 provides base current for P1. The collector current of P1 then provides additional base current for N1 and N2.

Once triggered, the positive feedback loop made up of P1, N1, and N3 conducts as long as there is voltage and current available to keep it on. This action also provides drive to the large NPN transistor N2, further clamping the voltage across the ESD rails 103 and 105. As the voltage across the ESD rails drops below the original trigger voltage, Z4 comes out of breakdown. The positive feedback action, however, keeps the clamp circuit 500 on pulling the voltage even lower. Eventually the voltage is pulled down to a point meeting the threshold voltage of Z3, so that current flow through Z3 stops. At this point N3 turns off, breaking the positive feedback loop formed by transistors P1 and N1 and turning off the ESD clamp circuit 500. In one embodiment, the holding voltage of the clamp 500 is greater than the nominal operating voltage which ensures that the clamp 500 does not stay latched when the device is powered up with its normal supply voltage. In summary the turn on voltage of the ESD clamp circuit 500 is set by Z3 plus Z4, and the turn off or holding voltage is set by Z3 alone. Both of these voltage set points are configured by selecting the threshold voltages of Z3 and Z4.

FIG. 6 is a schematic diagram of an ESD clamp circuit 600 with controlled hysteresis according to another embodiment using metal-oxide semiconductor (MOS) devices which may be used as the ESD clamp circuit 101. The ESD clamp circuit 600 is substantially similar to the ESD clamp circuit 300, except that PNP BJT P1 is replaced with PMOS P1, NPN BJT N1 is replaced with NMOS N1, and an NMOS device N2 is added in a similar manner as N2 was added for the ESD clamp circuit 400. Thus, the source of P1 is coupled to positive ESD rail 103, its gate is coupled to node 301, and its drain is coupled to node 303. The drain of N1 is coupled to Z2, its gate is coupled to node 303 and its source is coupled to the negative ESD rail 105. The drain of N2 is coupled to the positive ESD rail 103, its source is coupled to the negative ESD rail 105, and its gate is coupled to node 303. The resistors R1 and R2 are included and coupled in the same manner, although their resistive values may be adjusted according to MOS operation.

As before, Z1 sets the turn on voltage, Z2 sets the turn off voltage, P1 and N1 form a feedback loop, and N2 is the main clamping element. The turn on voltage is determined by the gate-to-source threshold voltage (VGS) of P1 plus the threshold voltage of Z1. The turn off voltage is determined by the VGS of P1 plus the threshold voltage of Z2 plus the drain-source saturation voltage (VDS_{SAT}) of N1.

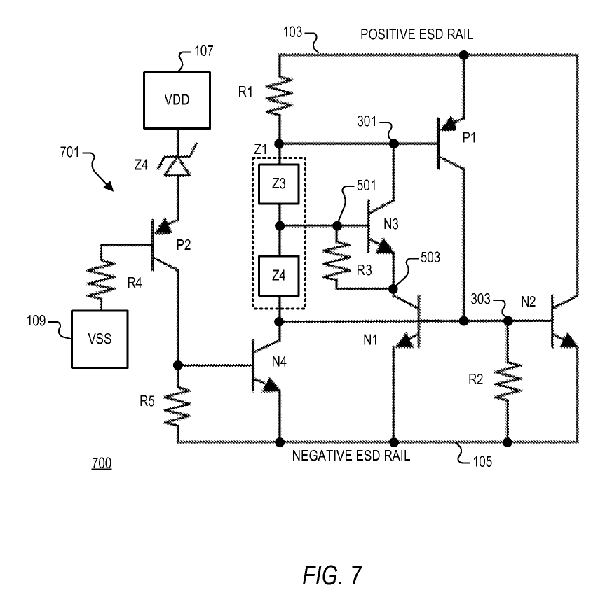

FIG. 7 is a schematic diagram of an ESD clamp circuit 700 with controlled hysteresis according to another embodiment including a disable circuit 701. The ESD clamp circuit 700 is similar to as the ESD clamp circuit 500 in which the disable circuit 701 is coupled to the negative ESD rail 105, node 303, and the source voltage pins 107 and 109. The disable circuit includes a Zener diode Z4, a PNP BJT P2, an NPN BJT N4, and a pair of resistors R4 and R5. Z4 has its cathode coupled to the VDD pin 107 and its anode coupled to the emitter of P2. P2 has its base coupled to one end of resistor R4 and its collector coupled to one end of resistor R5 and to the base of N4. The other end of resistor R4 is coupled to the VSS pin 109. The other end of the resistor R5 and the emitter of N4 are both coupled to the negative ESD rail 105.

Although not shown, the ESD clamp circuit 700 is useful for a quad diode bridge ultrasound switch fabricated using a high voltage oxide isolated complementary bipolar process. In one embodiment, the supply voltages for the device are +/−5 volts. However, under certain conditions the switch blocks the ultrasound transducer pulses which can be about +/−80 volts with 10 nanosecond (ns) rise and fall times. It is desired to provide ESD protection circuit for the chip, and thus only respond to actual ESD events, while ignoring the rather large and fast ultrasound pulses. It is difficult, however, to differentiate between ESD events and the ultrasound pulses because the ultrasound pulses have similar rise times to human body model (HBM) ESD events. Although magnitudes of the ultrasound pulses are not as large as an ESD pulse, both are well above the normal supply voltage and are difficult to distinguish.

The ESD clamp circuit 700 uses the presence or absence of the supply voltage to determine the mode of operation. It is determined that the ultrasound pulses are only present when the part is powered up. An ESD event, on the other hand, is most likely to occur while the part is powered down. In the ESD clamp circuit 700, Z4, P2, and R1 collectively detect whether the +/−5 volt supply is present. If the supplies are present, P1 turns on and provides base current for N2. When N2 turns on, it pulls the bases of N1 and N2 down making it difficult to turn these devices on and thus disabling the ESD clamp circuit 700. In this manner, the +/−80 volt ultrasound transducer pulse can be applied to the switch input pins without it being clamped by the ESD clamp circuit 700.

In one embodiment, Z3 and Z4 are both constructed by placing several 5V Zener diodes in series. For example, Z3 incorporates three 5V Zeners and Z4 incorporates thirteen 5V Zener diodes for a total of 16 Zener diodes. The total breakdown of the Z3+Z4 Zener stack is slightly over 80V. This voltage was selected to be higher than the 80V ultrasound pulse. In this embodiment, the holding voltage of the clamp 700 is roughly about 15V (as determined by the 3 5V Zener diodes coupled in series forming Z3), which ensures that the clamp 700 does not stay latched when the device is powered up with its normal 10V supply. In summary the avalanche voltage of the ESD clamp circuit 700 is set by Z3 plus Z4 and holding voltage is set by Z3 alone.

In one embodiment, each VT circuit Z1-Z4 of any of the ESD clamp circuits described herein is implemented with at least one device configured to have a particular threshold voltage level. As an example, Zener diodes are designed with a controlled breakdown voltage such that the Zener diode exhibits a voltage drop of the breakdown voltage when a reverse bias voltage equal to or greater than the breakdown voltage is applied. Zener diodes may be configured with a variety of different voltage levels, such as 3.2 volts (V), 5V, 5.6V, etc. Some common complementary MOS (CMOS) processes may not offer a Zener diode having the desired breakdown voltage levels. Even in such processes it is possible to configure such a device by connecting a P+ source drain implant to an N+ source drain implant and providing a contact on each side. Some analog CMOS processes offer a buried Zener that is designed to be used as a gate oxide protection diode. This device generally has a breakdown around 5V. Most bipolar processes offer a Zener diode in the 5V to 7V range. In any event, the Z1-Z4 elements may be made from any combination of devices that are used to establish a reference voltage such as forward diodes or diode-connected MOS transistors.

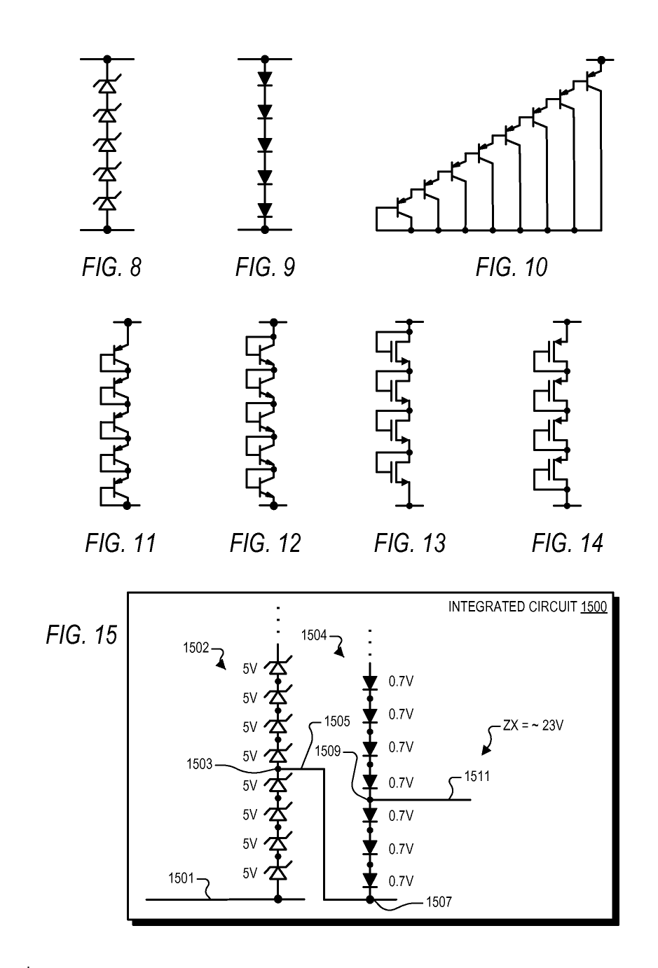

In an alternative embodiment, any one or more of the VT circuits Z1-Z4 of any of the ESD clamp circuits described herein is implemented as a series-coupled stack of voltage threshold (VT) devices. Each VT device has an associated voltage threshold level so that the stack of series-coupled VT devices has a total voltage threshold level which is determined by adding together the threshold voltages of the individual devices. Each VT circuit is configurable by selecting the type and number of voltage threshold devices to program a desired voltage threshold. Various types of VT devices are contemplated, such as reverse diodes or Zener diodes as shown in FIG. 8, forward diodes as shown in FIG. 9, Darlington-connected PNP transistors shown in FIG. 10, diode-connected PNP transistors as shown in FIG. 11, diode-connected NPN transistors as shown in FIG. 12, diode-connected NMOS (or NFET) transistors as shown in FIG. 13, diode-connected PMOS (or PFET) transistors as shown in FIG. 14, etc.

The VT circuit Z1-Z4 of any of the ESD clamp circuits described herein may further be implemented by combining VT devices of different voltage levels. FIG. 15 is a simplified schematic diagram of an integrated circuit 1500 pre-configured to implement a customizable VT circuit ZX according to one embodiment. A stack 1502 of 5V Zener diodes and another stack 1504 of 0.7V forward diodes are integrated on the IC 1500. A reference node 1501 at the bottom of the Zener diode stack 1502 forms a first terminal of the VT circuit ZX. An intermediate node 1503 of the Zener diode stack 1502 is selected to include 4 5V Zener diodes, and a conductor 1505 is routed from node 1503 to a node 1507 at the bottom of the forward diode stack 1504. An intermediate node 1509 of the forward diode stack 1504 is selected to add 3 0.7V forward diodes, and a conductor 1511 forms the second terminal of the VT circuit ZX. In this manner, the VT circuit ZX is formed with a selected threshold voltage of about 23V between first terminal 1501 and second terminal 1511. Alternative connections are made to customize any part with any selected threshold voltage level. In another embodiment, the individual voltage threshold devices are not pre-connected into a stacked configuration, but instead are stand-alone and not connected to each other. In this case, the voltage threshold devices are coupled together in any suitable order to program one or more VT circuits for use in the ESD clamp circuits.

An electrostatic discharge clamp as described herein is coupled between any first and second nodes of an electronic circuit in which it is desired to limit voltage to a predetermined maximum level to protect other electronic circuitry. Thus, the electrostatic discharge clamp turns on to dissipate voltage of an ESD pulse appearing between the nodes. The electrostatic discharge clamp circuit includes a clamp circuit and first and second voltage threshold circuits. The clamp circuit generally includes P-type and N-type devices, such as NPN and PNP bipolar junction transistors, P-channel and N-channel FETs, P-channel and N-channel MOS transistors, etc. Each P-type or N-type device may be implemented with one or more devices coupled in parallel (e.g., common drains, sources and gates, or common collectors, emitters and bases, or the like) to increase current-carrying capacity.

The clamp circuit may also include biasing devices, such as resistive devices and the like, which operate with the voltage threshold circuits to bias the clamp to turn on and off at selected threshold voltages. The clamp circuit remains off while the voltage across the first and second nodes is below a nominal operating voltage. The nominal operating voltage is generally determined by source voltage levels, such as VDD and VSS or any other pair of source voltages. The first and second nodes may be allowed to float within a higher voltage range within the nominal operating voltage. The first voltage threshold circuit is configured with a selected first threshold voltage, and operates to trigger and turn on the clamp circuit when the voltage between the first and second nodes increases above the first voltage threshold. In certain embodiments the voltage across the nodes rises above the first voltage threshold by one or more transistor junction voltages of the clamp circuit. In one embodiment, when the clamp circuit turns on, it forms a positive feedback loop to place the N-type and P-type devices in hard conduction to quickly dissipate the ESD pulse. The second voltage threshold circuit is configured with a selected second threshold voltage which is less than the first threshold voltage, so that it also turns on and draws current when the clamp circuit is turned on. When the clamp circuit turns on, it forms multiple current paths including current paths through the first and second voltage threshold circuits to dissipate the ESD pulse.

When the voltage across the nodes decreases below the first threshold voltage, even though the first voltage threshold circuit may be turned off and no longer draw current, the clamp circuit remains biased on until the voltage decreases to the second threshold voltage. At this point the second voltage threshold circuit turns off which turns off the entire electrostatic discharge clamp. Since the first and second threshold voltages are customizable, or selectable, or programmable or the like, the second threshold voltage may be configured at any desired voltage level greater than the nominal operating voltage. In this manner, the electrostatic discharge clamp not only provides ESD protection, it turns fully off and does not latch and thus allows the circuit to resume normal operation after the ESD pulse is dissipated.

Each of the first and second voltage threshold circuits includes one or more voltage threshold devices. Non-limiting examples of voltage threshold devices include reverse diodes, forward diodes, Darlington-connected NPN or PNP BJTs, diode-connected P-type or N-type devices, such as BJTs, FETs, MOS transistors, MOSFETs, etc. Two or more of the same or different types of voltage threshold devices may be coupled in parallel to form a stack of devices to form a voltage threshold circuit. An electrostatic discharge clamp as disclosed herein may be implemented on an IC and coupled between positive and negative ESD rails, which may be floated or coupled directly to corresponding source voltages. The IC may include multiple voltage threshold devices which are coupled together to form one or more of the voltage threshold circuits. Thus, the upper and lower threshold voltages of each IC may be customized according to particular specifications or needs including different ranges of source voltages.

Although the present invention has been described in considerable detail with reference to certain preferred versions thereof, other versions and variations are possible and contemplated. Those skilled in the art should appreciate that they can readily use the disclosed conception and specific embodiments as a basis for designing or modifying other structures for providing out the same purposes of the present invention without departing from the spirit and scope of the invention as defined by the following claims.

1. An electrostatic discharge clamp for coupling between first and second power rails, comprising:
first, second, third, and fourth nodes;
a first resistive device having a first terminal for coupling to the first power rail and having a second terminal coupled to said first node;
a second resistive device having a first terminal coupled to said second node and having a second terminal for coupling to the second power rail;
a third resistive device coupled between said third and fourth nodes;
a first transistor having a first current terminal coupled to said first terminal of said first resistive device, having a control terminal coupled to said first node, and having a second current terminal coupled to said second node;
a second transistor having a control terminal coupled to said second node, having a first current terminal coupled to said third node, and having a second current terminal coupled to said second terminal of said second resistive device;
a third transistor having a control terminal coupled to said fourth node, having a first current terminal coupled to said first node, and having a second current terminal coupled to said third node;
a first voltage threshold circuit coupled between said first and fourth nodes, wherein said first voltage threshold circuit has a selectable first threshold voltage, wherein said first voltage threshold circuit is turned off and does not conduct current when voltage across it is less than said first threshold voltage, and wherein said first voltage threshold circuit otherwise turns on to conduct current to clamp voltage across it at about said first threshold voltage; and
a second voltage threshold circuit coupled between said second and fourth nodes, wherein said second voltage threshold circuit has a selectable second threshold voltage, wherein said second voltage threshold circuit is turned off and does not conduct current when voltage across it is less than said second threshold voltage, and wherein said second voltage threshold circuit otherwise turns on to conduct current to clamp voltage across it at about said second threshold voltage.

2. The electrostatic discharge clamp of claim 1, wherein said first and second voltage threshold circuits are configured such that both are turned on when a supply voltage applied across the first and second power rails exceeds a sum of said first and second threshold voltages, and wherein said first and second voltage threshold circuits are configured such that both are turned off when said supply voltage falls below said second threshold voltage after having exceeded said sum of said first and second threshold voltages.

3. The electrostatic discharge clamp of claim 2, wherein the first and second power rails are configured to operate within a nominal operating voltage level which is less than said second threshold voltage, and wherein both of said first and second voltage threshold circuits are configured to be turned off when said supply voltage is within said nominal operating voltage level.

4. The electrostatic discharge clamp of claim 1, wherein said first transistor is of a first conductivity type and wherein said second and third transistors are both of a second conductivity type.

5. The electrostatic discharge clamp of claim 1, wherein said first transistor comprises a P-type transistor and wherein said second and third transistors each comprise an N-type transistor.

6. The electrostatic discharge clamp of claim 1, wherein said first and second voltage threshold circuits each comprises a stack of voltage threshold devices.

7. The electrostatic discharge clamp of claim 6, wherein said stack of voltage threshold devices comprises at least one diode.

8. The electrostatic discharge clamp of claim 1, further comprising a fourth transistor having a first current terminal coupled to said first terminal of said first resistive device, a second current terminal coupled to said second terminal of said second resistive device, and having a control terminal coupled to said second node.

9. The electrostatic discharge clamp of claim 1, further comprising:
a fourth transistor having a first current terminal coupled to said second node, having a second current terminal coupled to said second current terminal of said second transistor, and having a control terminal;
a fourth resistive device coupled between said control terminal and said second current terminal of said fourth transistor;
a fifth transistor having a first current terminal coupled to said control terminal of said fourth transistor, having a second current terminal and having a control terminal;
a third voltage threshold circuit coupled between a first supply voltage node and said second current terminal of said fifth transistor, wherein said third voltage threshold circuit has a selectable third threshold voltage, wherein said third voltage threshold circuit is turned off and does not conduct current when voltage across it is less than said third threshold voltage, and wherein said third voltage threshold circuit otherwise turns on to conduct current to clamp voltage across it at about said third threshold voltage; and
a fifth resistive device having a first terminal coupled to said control terminal of said fifth transistor and having a second terminal coupled to a second supply voltage node.

10. An integrated circuit, comprising:
a positive electrostatic discharge rail;
a negative electrostatic discharge rail; and
an electrostatic discharge clamp circuit, comprising:
first, second, third, and fourth nodes;
a first resistive device having a first terminal coupled to said positive electrostatic discharge rail and having a second terminal coupled to said first node;
a second resistive device having a first terminal coupled to said second node and having a second terminal coupled to said negative electrostatic discharge rail;
a third resistive device coupled between said third and fourth nodes;
a first transistor having a first current terminal coupled to said positive electrostatic discharge rail, having a control terminal coupled to said first node, and having a second current terminal coupled to said second node;
a second transistor having a control terminal coupled to said second node, having a first current terminal coupled to said third node, and having a second current terminal coupled to said negative electrostatic discharge rail;
a third transistor having a control terminal coupled to said fourth node, having a first current terminal coupled to said first node, and having a second current terminal coupled to said third node;
a first voltage threshold circuit coupled between said first and fourth nodes, wherein said first voltage threshold circuit has a selectable first threshold voltage, wherein said first voltage threshold circuit is turned off and does not conduct current when voltage across it is less than said first threshold voltage, and wherein said first voltage threshold circuit otherwise turns on to conduct current to clamp voltage across it at about said first threshold voltage; and
a second voltage threshold circuit coupled between said second and fourth nodes, wherein said second voltage threshold circuit has a selectable second threshold voltage, wherein said second voltage threshold circuit is turned off and does not conduct current when voltage across it is less than said second threshold voltage, and wherein said second voltage threshold circuit otherwise turns on to conduct current to clamp voltage across it at about said second threshold voltage.

11. The integrated circuit of claim 10, wherein said first and second voltage threshold circuits are configured such that both are turned on when a supply voltage applied across said positive and negative electrostatic discharge rails exceeds a sum of said first and second threshold voltages, and wherein said first and second voltage threshold circuits are configured such that both are turned off when said supply voltage falls below said second threshold voltage after having exceeded said sum of said first and second threshold voltages.

12. The integrated circuit of claim 11, wherein said positive and negative electrostatic discharge rails are configured to operate within a nominal operating voltage level which is less than said second threshold voltage, and wherein both of said first and second voltage threshold circuits are turned off when said supply voltage is within said nominal operating voltage level.

13. The integrated circuit of claim 10, wherein said first transistor is of a first conductivity type and wherein said second and third transistors are both of a second conductivity type.

14. The integrated circuit of claim 10, wherein said first transistor comprises a PNP bipolar transistor and wherein said second and third transistors each comprise an NPN bipolar transistor.

15. The integrated circuit of claim 10, wherein said first and second voltage threshold circuits each comprises a stack of voltage threshold devices.

16. The integrated circuit of claim 15, wherein said stack of voltage threshold devices comprises at least one diode.

17. The integrated circuit of claim 10, further comprising a fourth transistor having a first current terminal coupled to said positive electrostatic discharge rail, a second current terminal coupled to said negative electrostatic discharge rail, and having a control terminal coupled to said second node.

18. The electrostatic discharge clamp of claim 17, wherein said first transistor comprises a PNP bipolar transistor and wherein said second, third and fourth transistors each comprise an NPN bipolar transistor.

19. A method of clamping voltage between first and second voltage rails to dissipate an electrostatic pulse applied across the first and second voltage rails, comprising:
coupling a clamp circuit between the first and second voltage rails, wherein the clamp circuit is configured to limit voltage between the first and second voltage rails from increasing above a predetermined maximum level when activated;
coupling a first voltage threshold circuit having only two terminals between the first and second voltage rails and to a first node which is coupled to the clamp circuit, and configuring the first voltage threshold circuit with a first threshold voltage such that the first voltage threshold circuit is turned off and does not conduct current when voltage between its two terminals is less than the first threshold voltage, but is otherwise turned on to conduct current to clamp voltage between its two terminals to about the first threshold voltage;
coupling a second voltage threshold circuit having only two terminals between the first and second voltage rails and to the first node, and configuring the second voltage threshold circuit with a second threshold voltage such that the second voltage threshold circuit is turned off and does not conduct current when voltage between its two terminals is less than the second threshold voltage, but is otherwise turned on to conduct current to clamp voltage between its two terminals to about the second threshold voltage;
activating the clamp circuit only when both the first and second voltage threshold circuits are turned on, and deactivating the clamp circuit after being activated when both the first and second voltage threshold circuits are turned off.
selecting the first and second voltage thresholds such that when a voltage between the first and second voltage rails exceeds a first voltage limit which is greater than a normal operating voltage level, both of the first and second two-terminal voltage threshold circuits are turned on to activate the clamp circuit;
further selecting the first and second voltage thresholds such that after the clamp circuit is activated, when the voltage between the first and second voltage rails remains above a second voltage limit which is less than the first voltage limit and greater than the normal operating voltage level, keeping at least one of the first and second two-terminal voltage threshold circuits turned on to keep the clamp circuit activated; and
further selecting the first and second voltage thresholds such that after the clamp circuit is activated, when the voltage between the first and second voltage rails at or below the second voltage limit, turning off both of the first and second voltage threshold circuits to deactivate the clamp circuit.

20. The method of claim 19, wherein said selecting the first and second voltage thresholds comprises selecting one of the first and second voltage thresholds to determine the second voltage limit, and selecting a sum of the first and second voltage thresholds to determine the first voltage limit.
